(19) United States
(12) Patent Application Publication
(10) Pub. No.: US 2010/0271123 A1
(43) Pub. Date: Oct. 28, 2010

(54) ADAPTIVE DIGITAL PREDISTORTION OF COMPLEX MODULATED WAVEFORM USING LOCALIZED PEAK FEEDBACK FROM THE OUTPUT OF A POWER AMPLIFIER

(75) Inventors: Aracely W. Forrester, San Diego, CA (US); Philip D. Coan, La Jolla, CA (US); Paul J. Draxler, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/430,753

(22) Filed: Apr. 27, 2009

(51) Int. Cl. H03F 1/26

(52) U.S. Cl. 330/149

(57) ABSTRACT

Exemplary embodiments of the invention includes an amplifier and a processor that adapts a baseline or previous model of the input-output signal characteristic of the amplifier using metrics of the system, including peak power, peak voltage, average power, root mean square (RMS) voltage, samples of the output signal of the amplifier, etc. In particular, the system comprises an amplifier; a device to measure a metric of the system; a processor to generate a present model of the input-output signal characteristic of the amplifier based on the system metric as determined through a localized sampling window of the output signal; and a predistortion device to predistort the input signal for the amplifier based on the present amplifier model.

### BACKGROUND

1. Field

The present disclosure relates generally to radio frequency (RF) power amplifiers, and in particular, to a system and method of performing adaptive digital predistortion (DPD) of complex modulated waveform based on metrics of a system, such as localized waveform peak power or voltage from the output of an RF power amplifier.

2. Background

In the wireless communications field, there is a general need for devices capable of transmitting more data within a given bandwidth, and at the same time achieving a reasonable or optimal power efficiency to conserve battery power. For instance, wireless devices have been designed with different modulation schemes, such as quadrature amplitude modulation (QAM) having 16, 32, or 64 constellations, to increase the data throughput within a given bandwidth. Additionally, wireless devices have also been designed using power amplifiers that operate close to their saturation region, such as class A/B, B, C, and other class amplifiers, to improve the power consumption efficiency.

Because of the relatively high spectral efficiency of the data transmission, such wireless devices often have tight requirements on the allowable spectral leakage. In some cases, these requirements present a problem for operating power amplifiers close to their saturation regions because the nonlinearity characteristic of the amplifier causes significant spectral re-growth and in-band distortion. One solution is to backoff the operation of the amplifier into its linear region so as to reduce or prevent this distortion. However, this results in reduced power efficiency for the device, which has adverse impact on the battery life and continued use of the device.

Another solution is to operate the power amplifier near its saturation or nonlinear region, and use a predistortion device at the input of the amplifier to distort the input signal so as to correct or reduce the distortion of the output signal caused by the nonlinearity of the amplifier. There are generally two approaches: an open loop approach and a closed loop approach. The open loop approach typically works well as long as the nonlinear characteristic of the amplifier is accurately modeled and does not significantly change over time with environmental conditions. The closed loop approach involves providing adaptation to the predistortion device so that it can model the nonlinear characteristic of the power amplifier in “real time,” and adjust the predistortion of the input signal in accordance with the present model of the amplifier. However, often these adaptation techniques are complicated and expensive, as discussed as follows.

FIG. 1 illustrates a block diagram of a typical closed loop transmitter system 100 that uses a demodulation technique to provide information about an output signal in order to apply predistortion of an input signal to compensate for distortion in the output signal caused by a power amplifier. In particular, the transmitter system 100 includes a digital predistortion (DPD) device 102, a digital-to-analog converter (DAC) 104, an automatic gain control (AGC) 106, an up converting mixer 108, and a power amplifier 110. The transmitter system 100 further includes a demodulation section including a power splitter 112, a pair of mixers 114 and 116, an oscillator 120, a 90° phase shifter 118, and a pair of filters 122 and 124.

The DPD device 102 predistorts an input baseband or intermediate frequency (IF) digital signal based on signals received from the demodulation section in order to achieve a target signal at the output of the power amplifier 110. The DAC 104 converts the predistorted digital signal from the DPD device 102 into an analog signal. The AGC 106 dynamically amplifies or attenuates the analog signal in order to achieve a target power level for the signal at the output of the power amplifier 110. The up converter mixer 108 uses a local oscillator (L.O.) to upconvert the baseband or IF analog signal into a radio frequency (RF) signal. The power amplifier 110 amplifies the RF signal to generate an output RF signal.

The demodulation section converts a sampled portion of the output RF signal into an I/Q IF or baseband signals for use by the DPD device 102 in predistorting the input digital signal to achieve a target RF output signal for the transmitter 100. The power splitter 112 splits the sampled output RF signal into two components for processing by the I- and Q-portions of the demodulation section. The mixer 114 uses the signal from the oscillator 120 to down convert the sampled output RF signal into an I-component IF or baseband signal. The filter 122 removes high order frequency components from the I-signal. Similarly, the mixer 116 uses the signal from the oscillator 120 shifted in phase by 90 degrees by the phase shifter 118 to down convert the sampled output RF signal into a Q-component IF or baseband signal. The filter 124 removes high order frequency components from the I-signal.

There are many drawbacks with the demodulation approach. For instance, the circuitry is very complex requiring a demodulation section to generate I- and Q-IF or baseband signals for use by the DPD device in predistorting the input digital signal to achieve a target output signal. The complexity is further underscored by the fact that the I- and Q-signals should be time aligned with the input signal for the system to operate properly. Further, the I- and Q-demodulation generally requires predistortion both in the amplitude domain and in the phase domain. Usually, a higher resolution DAC is required when predistorting of the input signal occurs in both the amplitude and frequency domains.

### BRIEF DESCRIPTION OF THE DRAWINGS

FIG. 1 illustrates a block diagram of a typical closed loop transmitter system that uses a demodulation technique to provide information about an output signal in order to apply predistortion of an input signal to compensate for distortion in the output signal caused by a power amplifier.

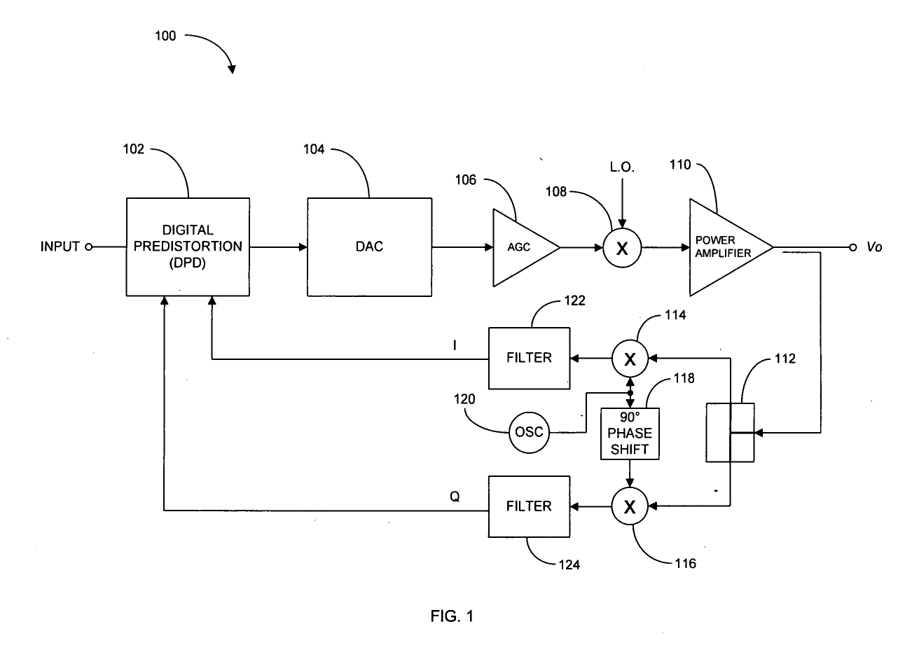

FIG. 2 illustrates a block diagram of an exemplary transmitter system including a power amplifier with an adaptive predistortion device in accordance with an exemplary embodiment of the disclosure.

FIG. 3 illustrates a flow diagram of an exemplary method of adapting an amplifier model using a localized sampling window and using the adapted amplifier model to predistort an input signal to achieve a target output signal in accordance with another exemplary embodiment of the disclosure.

FIG. 4 illustrates a signal flow diagram of an exemplary method of adapting an amplifier model using a localized sampling window for activating an output signal peak detector in accordance with an exemplary embodiment of the disclosure.

FIG. 5 illustrates a localized sampling window including an output waveform under analysis in accordance with an exemplary embodiment of the disclosure.

FIG. 6 illustrates a localized sampling window bounds in accordance with an exemplary embodiment of the disclosure.

FIG. 7 illustrates alignment of a control trigger signal with a localized sampling window in accordance with an exemplary embodiment of the disclosure.

FIG. 8A-D illustrates flow diagrams of exemplary methods of determining characteristics of a present amplifier model in accordance with an exemplary embodiment of the disclosure.

FIG. 9 illustrates a graph of exemplary gain responses of a power amplifier pertaining to an exemplary baseline amplifier model, an exemplary adapted amplifier model where the low power gain has been adjusted higher, and an exemplary adapted amplifier model where the low power gain has been adjusted lower in accordance with another exemplary embodiment of the disclosure.

FIG. 10 illustrates a graph of exemplary saturation voltage responses of a power amplifier pertaining to an exemplary baseline amplifier model, an exemplary adapted amplifier model where the saturation voltage has been adjusted higher, and an exemplary adapted amplifier model where the saturation voltage has been adjusted lower in accordance with another exemplary embodiment of the disclosure.

FIGS. 11A-C illustrate graphs of an exemplary normalized output-input voltage responses for the exemplary power amplifier, the predistortion device, and the transmitter system in accordance with another exemplary embodiment of the disclosure.

FIG. 12 illustrates a graph of an exemplary peak-to-average power ratio versus output power for the input, output, and target output of the power amplifier in accordance with another exemplary embodiment of the disclosure.

FIG. 13A illustrates a time-domain graph of exemplary undistorted or original input and distorted output signals in accordance with another exemplary embodiment of the invention.

FIG. 13B illustrates a time-domain graph of exemplary predistorted input and output signals in accordance with another exemplary embodiment of the invention.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

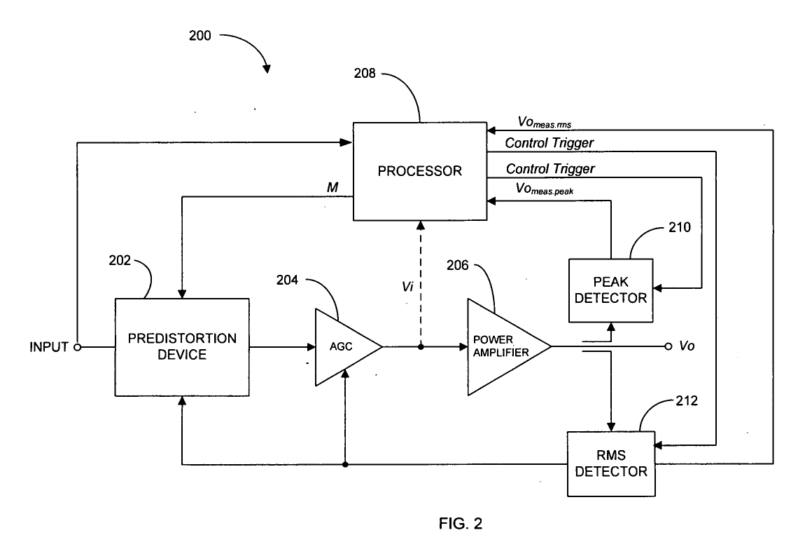

FIG. 2 illustrates a block diagram of an exemplary transmitter system 200 including a power amplifier, an adaptive amplifier modeling device, and a predistortion device in accordance with an exemplary embodiment of the disclosure. In summary, the transmitter system 200 measures the average power or root mean square (RMS) voltage and peak power or peak voltage occurring in a sampling window of the output signal generated by the power amplifier, and uses these inputs to build a model of the input-output signal characteristic of the power amplifier from a baseline or predetermined amplifier model. The transmitter system 200 further includes a predistortion device that modifies an input signal based on the adapted amplifier model to achieve a target output signal for the power amplifier.

In particular, the transmitter system 200 comprises a predistortion device 202, an automatic gain control (AGC) device 204, a power amplifier 206, a processor 208, a peak power or voltage detector 210, and an average power or RMS voltage detector 212. As discussed in more detail below, the predistortion device 202 distorts an input RF signal to achieve a target output RF signal for the power amplifier 206, such as to correct or reduce distortion of the output signal due to the nonlinearity characteristics of the transmitter 200, which includes power amplifier 206. The predistortion device 202 distorts the input RF signal based on an adapted amplifier model M of the power amplifier 206 developed by the processor 208.

The automatic gain control (AGC) device 204 modifies the power level of the predistorted RF signal generated by the predistortion device 202 in response to the measured average power or RMS voltage of the output RF signal as indicated by the RMS detector 212. One of the purposes of the AGC device 204 is to control the power level of the output RF signal. The power amplifier 206 amplifies the RF signal from the output of the AGC device 204 to generate the output RF signal Vo. As previously discussed, the power amplifier 206 may be operated in its nonlinear or near saturation region to improve the power efficiency of the transmitter system 200. As a result, the nonlinearity characteristic of the power amplifier 206 distorts the output RF signal, which is corrected or reduced by the predistorting of the input RF signal provided by the predistortion device 202.

As discussed in more detail below, the processor 208 builds an amplifier model M of the present input-output signal characteristic of the power amplifier 206. The processor 208 identifies a sampling window of interest in the input RF signal based upon knowledge of a localized peak in the waveform over a target sampling window and generates a control trigger signal. The processor 208 develops the model from the measured or estimated input signal Vᵢ of the power amplifier 206, the measured peak power or voltage Vo_{meas.peak} of the output RF signal over the sampling window as indicated by the peak detector 210, the measured average power or RMS voltage Vo_{meas.rms} of the output RF signal over the sampling window as indicated by the RMS detector 212, and a baseline or predetermined amplifier model. The processor 208 sends the adapted amplifier model M to the predistortion device 202, which uses the model in order to predistort the input RF signal to achieve a target or specified output RF signal. The following describes in more detail the amplifier model adaptation procedure performed by the processor 208, and the input signal predistorting procedure performed by the predistortion device 202.

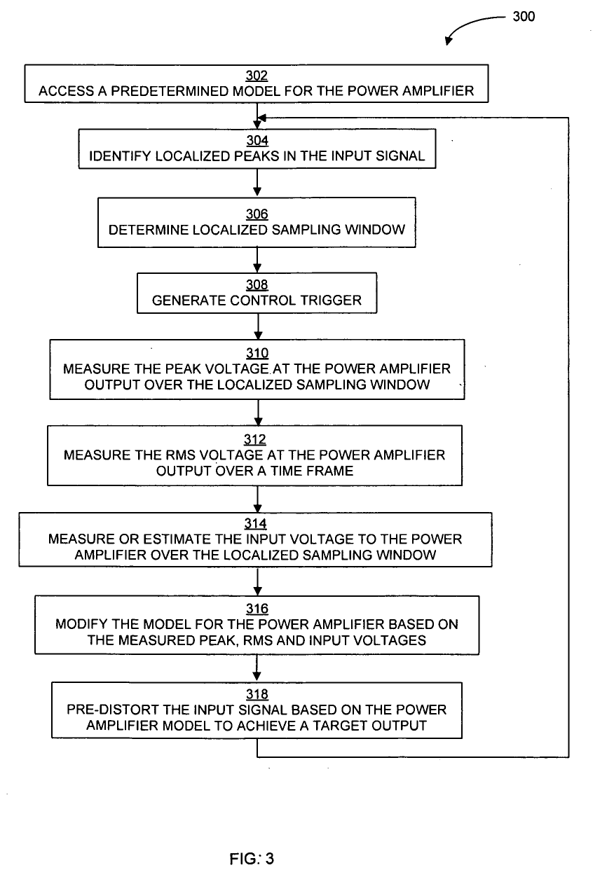

FIG. 3 illustrates a flow diagram of an exemplary method 300 of adapting an amplifier model, and using the adapted amplifier model to predistort an input signal to achieve a target output signal in accordance with another exemplary embodiment of the disclosure. In any of the concepts described herein, the order of performance is exemplary, and any order can be used which achieves substantially the same results. According to the method 300, the processor 208 accesses a baseline or predetermined amplifier model for the power amplifier 206 (block 302). The baseline amplifier model may have been developed by testing one or more of the same power amplifiers over some operational range (e.g., temperature, power supply voltage, frequency, etc.). The predetermined amplifier model may be a median or average of the performance characteristics of a sample set of the same type amplifiers. Optimally, this model should substantially minimize the error between the predetermined model and the actual performance of the power amplifier 206, or other suitable models based on other tests and/or observations.

Transmitter 200 may generate a rudimentary amplifier model based on an absolute peak power over an entire frame or other large signal segment. However, refined amplifier models require analysis of nonlinearities occurring between the absolute peak values. In the exemplary method, transmitter 208 generates the amplifier model based on an analysis of localized peaks of the output RF signal. Analysis of localized peaks results in additional sample points used to refine the amplifier model. During normal operation of the transmitter system 200, the processor 208 analyzes the input signal to obtain knowledge of a localized target peak (block 304). The localized target peak may be selected based upon a desired power (e.g., 70% of the absolute peak for a frame).

Once the localized target peak of the input signal has been identified, the processor 208 determines a localized sampling window (block 306) for applying to the output RF signal which will include the amplified localized target peak. The localized sampling window may be based upon sampling window constraints including propagation delay associated with, for example, group delay. Accordingly, the processor 208 determines the delay between detection of a localized target peak on the input signal by the processor 208 to the amplified localized peak appearing at the output RF signal. Based upon the determined propagation delay, the processor 208 generates a control trigger signal (block 308) signaling the timing of the localized sampling window to the peak detector 210.

In response to the control trigger signal, the processor 208 measures or estimates (block 310) the peak power or voltage Vo_{meas.peak} of the output RF signal of the power amplifier 106 as indicated by the peak detector 210 for a sequence of n samples over the localized sampling window. The processor 208 also measures or estimates (block 312) the average power or RMS peak voltage Vo_{meas.rms} of the output RF signal of the power amplifier 206 as indicated by the RMS detector 212 for the sequence of n samples over the localized sampling window. Additionally, the processor 208 measures or estimates (block 314) the input voltage Vi (the RF signal at the input of the power amplifier 206) for the sequence of n samples over the localized sampling window.

Based on these three inputs, e.g., the measured peak voltage Vo_{meas.peak}, the measured RMS voltage Vo_{meas.rms}, and the measured or estimated input voltage Vᵢ, the processor 208 modifies the baseline or predetermined amplifier model so that it better reflects the actual performance of the power amplifier 206 (block 316). The processor 208 then sends the adapted (present) amplifier model to the predistortion device 202, which uses the present model to predistort the input signal to achieve a target or specified output RF signal for the transmitter system 200 (block 318). The method 300 then continues to block 304 where the process is repeated again. That is, the processor 208 again identifies a localized peak of interest, determines a localized sampling window, generates a control trigger signal, measures the voltages Vo_{meas.peak}, Vo_{meas.rms}, and the measured or estimated input voltage Vi per respective blocks 304, 306, 308, 310, 312 and 314 and then adapts the previous amplifier model developed in the prior cycle based on these new measurements (block 316). Alternatively, in block 316, the processor 208 may adapt the baseline or predetermined amplifier based on the new measurements. Again, per block 318, the predistortion model uses the adapted (present) amplifier model to distort the input RF signal to achieve a target or specified output RF signal. The method 300 continues to repeat operation blocks 304 through 318 as desired or specified. Any of the above-described operations may have appropriate validity checks to ensure that the adapted amplifier model substantially reflects the actual performance of the amplifier.

The specifics of the determination of the localized sampling window will not be discussed. It shall be understood that the following is merely one example of a determination of a localized sampling window. In an exemplary method for determining a localized sampling window, the processor 208 uses knowledge of the input signal (RF or baseband) to turn on the peak detector to capture the desired peak in the output RF signal at the output of the power amplifier.

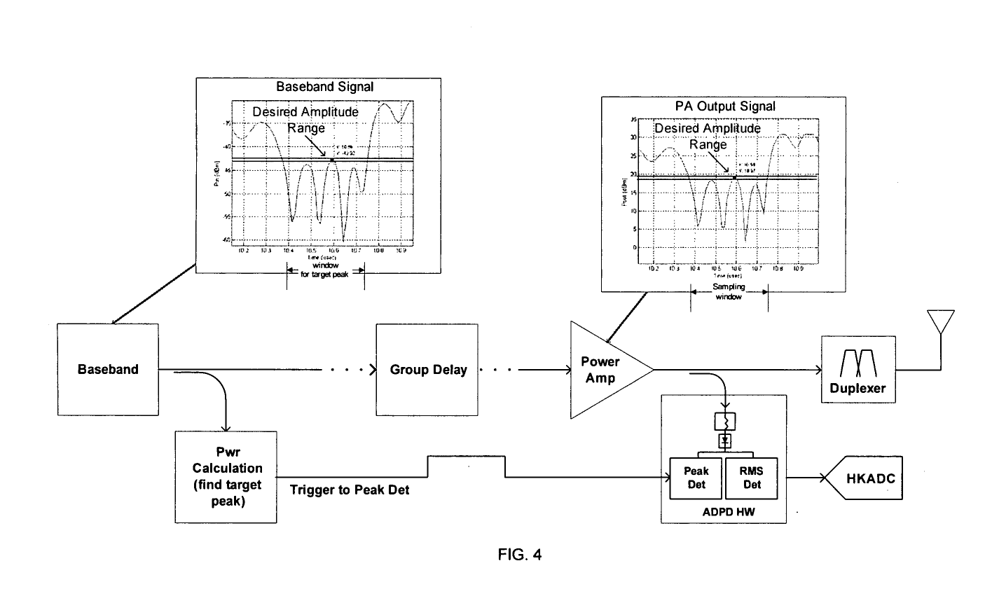

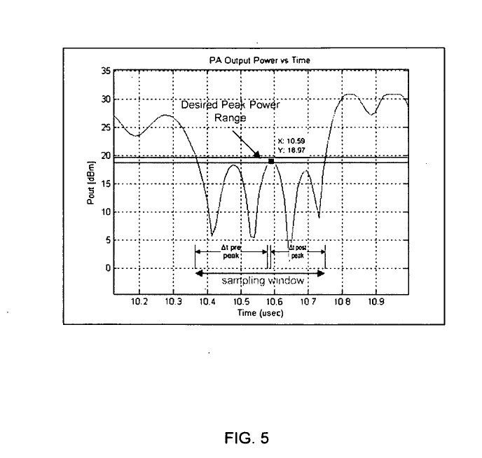

FIG. 4 is a signal flow diagram including various components of transmitter system 200 and FIG. 5 illustrates a localized sampling window including an output RF signal waveform in accordance with an exemplary embodiment of the disclosure. The localized sampling window criteria includes determining the sampling window constraints and identifying the control trigger timing. First, a timing window which includes the desired target peak as the highest peak therein is determined. Input signal (RF or baseband) peak power calculations will identify how much time is available before and after the desired peak occurs before getting overridden by a higher peak. The time before the peak occurs where the desired is peak is dominant, is defined as Δt_pre_peak. The time after the desired peak occurs while the desired peak is still dominant, is defined as Δt_post_peak. These two variables, as illustrated in FIG. 5, determine the sampling window where the desired peak is the highest peak. Therefore, the Sampling window=Δt_pre_peak+Δt_post_peak.

As a practical matter, the largest possible sampling window would be desirable to ease hardware implementation requirements. However, design tradeoffs exist between the localized sampling window length and the resulting number of target peaks found in, for example, one OFDM frame. Generally, for larger sampling windows, there are less opportunities in a single OFDM frame of having the target peak be the largest peak in the sampling window. Additionally, if the power amplifier is operating at maximum power, the smaller peaks require smaller sampling windows to ensure capturing the smaller peaks compared to the larger peaks.

Furthermore, choosing a sampling window too small ignores peak detector slewing and signal path group delay tolerances. Whereas a large sampling window gives the peak detector limited opportunities, for example, in a single OFDM frame for capturing the target peak. In practical implementations, extra timing margin may be required to account for peak detector slewing and other circuit variations. By way of example, sampling window minimum bound may be defined as:

Δt_pre_peak=peakdet_slewrate/2+2*group_delay_tol

Δt_post_peak=peakdet_slewrate/2+2*group_delay_tol.

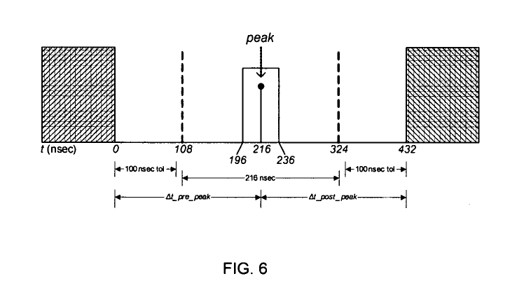

FIG. 6 illustrates localized sampling window bounds in accordance with an exemplary embodiment. As illustrated by way of example, the minimum sampling window bounds of Δt_pre_peak and Δt_post_peak≧215 nsec. The 50 nsec window around the peak accounts for peak detector slewing. The additional 100 nsec intervals before and after the target peak accounts for signal path group delay variations.

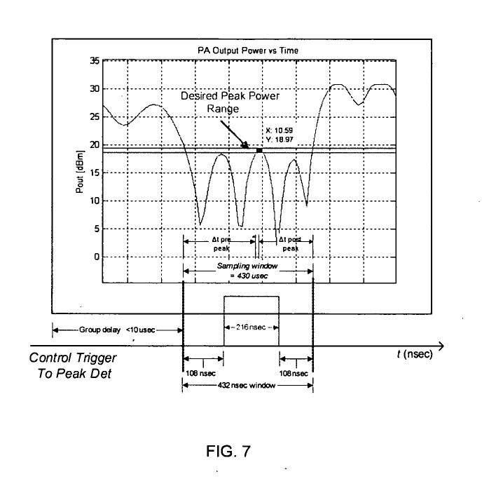

FIG. 7 illustrates alignment of a control trigger signal with the localized sampling window in accordance with an exemplary embodiment. The processor 208 determines a timing relationship between the localized sampling window and the peak detector control trigger signal. The control trigger signal path and the signal path group delay are synchronized in time to define when the peak detector is activated. FIG. 7 further illustrates relationships of the time location of the desired peak and the localized sampling window length and the determination of activation of the control trigger signal. In one exemplary embodiment, the control trigger signal is activated during approximately half of the localized sampling window as shown in FIG. 7.

In implementation, the signal path group delay is determined (estimated, calibrated, etc.) in order to synchronize the control trigger signal to the peak detector. Furthermore, since the group delay is typically larger than the localized sampling window length, the processor 208 is able to perform the peak power calculations. The processor 208 performs the power calculations to find the target peak within a desired power range and minimum sampling window length. Upon finding the target peak, the control trigger signal, as synchronized with the group delay and sampling window constraints, is sent to the peak detector. The time duration when the control trigger signal is asserted indicates that the peak detector is turned on and ready to capture the target peak and hold the peak voltage. Deassertion of the control trigger signal deactivates the peak detector and the peak value is stored, for example, in a holding capacitor (not shown). The stored peak voltage may be sampled by an analog-to-digital converter (ADC) as illustrated in FIG. 4. The holding capacitor is then reset (discharged) for a subsequent operation. The described localized sampling window and the peak detector provide feedback to the processor 208 for adjusting the power amplifier model as described above. As stated, the detected power levels are localized peaks within the target localized sampling window.

The specifics of the amplifier model adaptation process will now be discussed. It shall be understood that the following is merely one example of an amplifier model adaptation process that uses the measured peak and RMS voltages from the output of the power amplifier to adapt the model for the present performance of the power amplifier. The amplifier model may be configured as a look-up table (LUT) indicating an input signal characteristic, such as the input amplitude Viₜ(k)ᵢ and a corresponding output signal amplitude Voₜ(k)ᵢ, where k is the index for the look-up table and the subscript “i” indicates the present adaptation cycle. For example, if i=0, then the input and output amplitude characteristics Viₜ(k)₀ and Voₜ(k)₀ pertain to the baseline or predetermined amplifier model. If i=1, then the input and output amplitude characteristics Viₜ(k)₁ and Voₜ(k)₁ pertain to the adapted amplifier model after the completion of the first adaptation cycle. At any point in time, if a model is determined to be in error, it can be reset to the baseline or predetermined model.

The processor 208 may first determine the saturated voltage Voₛₐₜ₍ᵢ₋₁₎ and low power gain Gₗₚ₍ᵢ₋₁₎ pertaining to the previous amplifier model, using the following equations:

Voₛₐₜ₍ᵢ₋₁₎=max(Voₜ(k)₍ᵢ₋₁₎) Eq. 1

Glp₍ᵢ₋₁₎=Voₜ(2)₍ᵢ₋₁₎/Viₜ(2)₍ᵢ₋₁₎ Eq. 2

Where max(Voₜ(k)₍ᵢ₋₁₎) is the maximum of the output amplitude characteristic of the previous amplifier model, and Viₜ(2)₍ᵢ₋₁₎ and Voₜ(2)₍ᵢ₋₁₎ are the second entry (k=2) of the input and output amplitude characteristics of the previous amplifier model. In this example, the second entry may be used because the first entry ((k=1)) may have significant noise associated with it because of the relatively small input voltage.

Then, the processor 208 measures or estimates n values of the voltage Vi at the input of the power amplifier 206. The processor 208 then determines which input amplitude characteristic Viₜ(k(Vi)))₍ᵢ₋₁₎ of the previous amplifier model corresponds to the measured or estimated voltage Viᵢ. The processor 208 then uses this characteristic to estimate the gain G(Vi)₍ᵢ₋₁₎ of the power amplifier 206 by using the following equation:

G(Viᵢ)₍ᵢ₋₁₎=Voₜ(k(Viᵢ))₍ᵢ₋₁₎/Viₜ(k(Viᵢ))₍ᵢ₋₁₎ Eq. 3

Where Voₜ(k(Viᵢ))₍ᵢ₋₁₎ is the output amplitude characteristic of the previous amplifier model corresponding to the input amplitude characteristic Viₜ(k(Viᵢ))₍ᵢ₋₁₎. The processor 208 may then determine the estimated output voltage Vo_{i.est} corresponding to the measured or estimated input voltage Viᵢ using the following equation:

Vo_{i.est}=G(Viᵢ)*Viᵢ Eq. 4

The processor 208 may also determine the estimated RMS output voltage Vo_{i.est.rms} from the estimated output voltage Vo_{1.est} using the following equation:

$${Vo}_{i . est . rms} = \sqrt{\frac{{\sum }_{1}^{n} {{Vo}_{i . est}}^{2}}{n}} \qquad Eq . 5$$

Where n is the number of samples taken of the voltage Viᵢ at the input of the power amplifier for the specified frame. The processor 208 further determines the estimated output peak voltage Vo_{i.est.peak} by using the following equation:

Vo_{i.est.peak}=max[Vo_{i.est}]for set{Viᵢ₁ . . . Viᵢₙ} Eq. 6

Where {Viᵢ₁ . . . Viᵢₙ} is the set of n values of the input voltage Viᵢ for the specified frame.

The processor 208 then measures or estimates the current peak voltage Vo_{i.meas.peak} and the current RMS voltage Vo_{i.meas.peak} of the output of the power amplifier 206. Using the measured RMS voltage, the processor 208 may then determine the present low power gain Glpᵢ of the power amplifier 206 using the following equation:

$${Glp}_{i} = {Glp}_{( i - 1 )} \cdot \frac{{Vo}_{i . meas . rms}}{{Vo}_{i . est . rms}} \qquad Eq . 7$$

The processor 208 may also determine the present saturated voltage Voₛₐₜᵢ using the following equation:

$${{Vo}_{sat}}_{i} = {Vo}_{sat ( i - 1 )} \cdot \frac{{Vo}_{i . meas . peak}}{{Vo}_{i . est . peak}} \qquad Eq . 8$$

The processor 208 may then determine the input amplitude characteristic Viₜ(k)ᵢ of the adapted amplifier model using the following equation:

$${{Vi}_{t} ( k )}_{i} = {{Vi}_{t} ( k )}_{( i - 1 )} \cdot \frac{{Vo}_{sati} / {Glp}_{i}}{{Vo}_{sat ( i - 1 )} / {Glp}_{( i - 1 )}} \qquad Eq . 9$$

The processor 208 may also determine the output amplitude characteristic Voₜ(k)ᵢ of the adapted amplifier model using the following equation:

$${{Vo}_{t} ( k )}_{i} = {{Vo}_{t} ( k )}_{( i - 1 )} \cdot \frac{{Glp}_{i}}{{Glp}_{( i - 1 )}} \cdot \frac{{{Vi}_{t} ( k )}_{i}}{{{Vi}_{t} ( k )}_{( i - 1 )}} \qquad Eq . 10$$

And, as previously discussed, the adapted (present) amplifier model Viₜ(k)ᵢ and Voₜ(k)ᵢ may be used by the predistortion device 202 to predistort the input RF signal to the transmitter system 200 to achieve a target or specified output signal at the output of the power amplifier 206. This process may be continually repeated to adapt the amplifier model to better reflect its current performance.

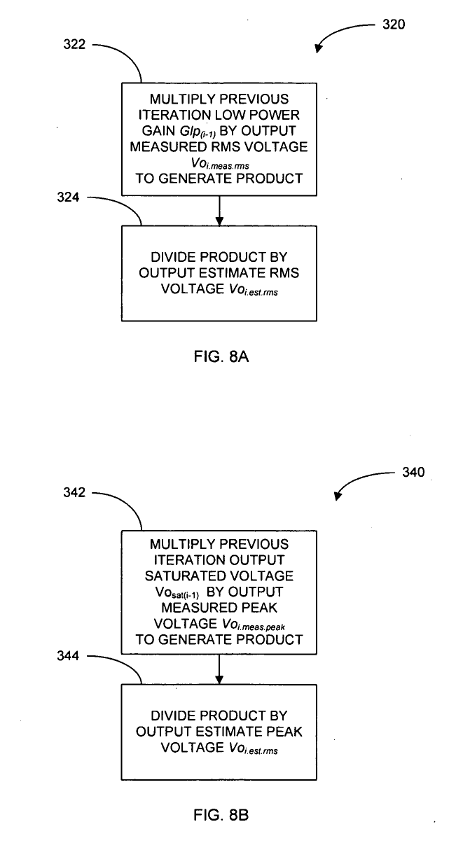

FIG. 8A illustrates a flow diagram of an exemplary method 320 of determining a present low power gain Glpᵢ of a present amplifier model in accordance with another exemplary embodiment of the disclosure. As previously discussed, the method 320 may be one of a number of operations performed in a process of developing a present amplifier model. Although the method 320 is described with reference to a particular order of steps, it shall be understood that the method may be implemented in any particular order and steps to achieve substantially the same results.

In particular, according to the method 320, the low power gain Glp₍ᵢ₋₁₎ associated with a previous iteration of determining a previous amplifier model is multiplied by the measured RMS voltage Vo_{i.meas.rms} of an output signal of the amplifier to generate a product (block 322). Then, according to the method 320, the product generated according to block 322 is divided by an estimate RMS voltage Vo_{i.est.rms} of the output signal of the amplifier to generate the present low power gain Glpᵢ (block 324).

FIG. 8B illustrates a flow diagram of an exemplary method 340 of determining a present saturated voltage Voₛₐₜᵢ of a present amplifier model in accordance with another exemplary embodiment of the disclosure. As previously discussed, the method 340 may be one of a number of operations performed in a process of developing a present amplifier model. Although the method 340 is described with reference to a particular order of steps, it shall be understood that the method may be implemented in any particular order and steps to achieve substantially the same results.

In particular, according to the method 340, the saturated voltage Voₛₐₜ₍ᵢ₋₁₎ associated with a previous iteration of determining a previous amplifier model is multiplied by the measured peak voltage Vo_{i.meas.peak} of an output signal of the amplifier to generate a product (block 342). Then, according to the method 340, the product generated according to block 342 is divided by an estimate peak voltage Vo_{i.est.peak} of the output signal of the amplifier to generate the present saturated voltage Voₛₐₜᵢ (block 344).

FIG. 8C illustrates a flow diagram of an exemplary method 360 of determining an input amplitude characteristic Viₜ(k)ᵢ of a present amplifier model in accordance with another exemplary embodiment of the disclosure. As previously discussed, the method 360 may be one of a number of operations performed in a process of developing a present amplifier model. Although the method 360 is described with reference to a particular order of steps, it shall be understood that the method may be implemented in any particular order and steps to achieve substantially the same results.

In particular, according to the method 360, the saturated voltage Voₛₐₜᵢ associated with a present iteration of determining a present amplifier model is divided by the low power gain Glpᵢ associated with the present iteration of determining the present amplifier model to generate a first quotient (block 362). Then, according to the method 360, the saturated voltage Voₛₐₜ₍ᵢ₋₁₎ associated with a previous iteration of determining a previous amplifier model is divided by the low power gain Glp₍ᵢ₋₁₎ associated with the previous iteration of determining the previous amplifier model to generate a second quotient (block 364). Then, according to the method 360, the first quotient generated according to block 362 is divided by the second quotient generated according to block 364 to generate a third quotient (block 366). Then, according to the method 360, the third quotient generated according to block 366 is multiplied by an input amplitude characteristic Viₜ(k)ᵢ₋₁₎ associated with the previous amplifier model, to generate the input amplitude characteristic Viₜ(k)ᵢ of the present amplifier model (block 368).

FIG. 8D illustrates a flow diagram of an exemplary method 380 of determining an output amplitude characteristic Voₜ(k)ᵢ of a present amplifier model in accordance with another exemplary embodiment of the disclosure. As previously discussed, the method 380 may be one of a number of operations performed in a process of developing a present amplifier model. Although the method 380 is described with reference to a particular order of steps, it shall be understood that the method may be implemented in any particular order and steps to achieve substantially the same results.

In particular, according to the method 380, the low power gain Glpᵢ associated with a present iteration of determining a present amplifier model is divided by the low power gain Glp₍ᵢ₋₁₎ associated with a previous iteration of determining a previous amplifier model to generate a first quotient (block 382). Then, according to the method 380, the input amplitude characteristic Viₜ(k)ᵢ associated with the present iteration of determining the present amplifier model is divided by an input amplitude characteristic Viₜ(k)₍ᵢ₋₁₎ associated with the previous iteration of determining the previous amplifier model to generate a second quotient (block 384). Then, according to the method 380, the first quotient generated according to block 382 is multiplied by the second quotient generated according to block 384 to generate a product (block 386). Then, according to the method 380, the product generated according to block 386 is multiplied by an output amplitude characteristic Voₜ(k)₍ᵢ₋₁₎ associated with the previous amplifier model, to generate the output amplitude characteristic Voₜ(k)ᵢ of the present amplifier model (block 388).

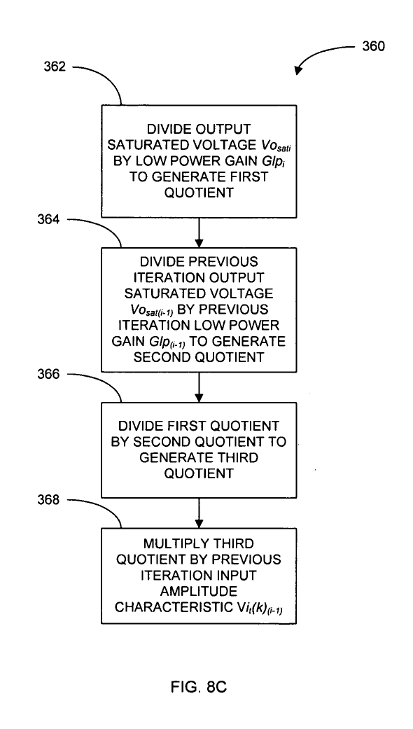

FIG. 9 illustrates a graph of exemplary gain responses of a power amplifier pertaining to an exemplary baseline amplifier model, an exemplary adapted amplifier model where the low power gain has been adjusted higher, and an exemplary adapted amplifier model where the low power gain has been adjusted lower in accordance with another exemplary embodiment of the disclosure. As seen from the graph, the baseline amplifier model depicts a typical gain response for a power amplifier. It is typically characterized as having a gain that initially rises from a low power gain, in this example being approximate 27 dB, to a peak gain, in this example being approximately 29.3 dB. The rise in the gain is typically referred to as a gain expansion region. After the gain expansion region, the gain begins to decline due to the saturation characteristic of the power amplifier.

If, for example, in the first adaptation cycle the measured RMS voltage of the output RF signal of the power amplifier 106 is greater than the estimated RMS voltage of the output RF signal, then according to Eq. 7, the low power gain of the new amplifier model is greater than the low power gain of the baseline amplifier model. According to Eqs. 9 and 10, the effects of a higher low power gain produces an increase to the overall gain response of the adapted power amplifier model, as indicated by the graph. If, on the other hand, in the first adaptation cycle the measured RMS voltage of the output RF signal is less than the estimated RMS voltage of the output RF signal, then the low power gain of the adapted power amplifier model is less than the low power gain of the baseline amplifier model. The effects of a lower low power gain produces a decrease to the overall gain response of the power amplifier model, as indicated by the graph.

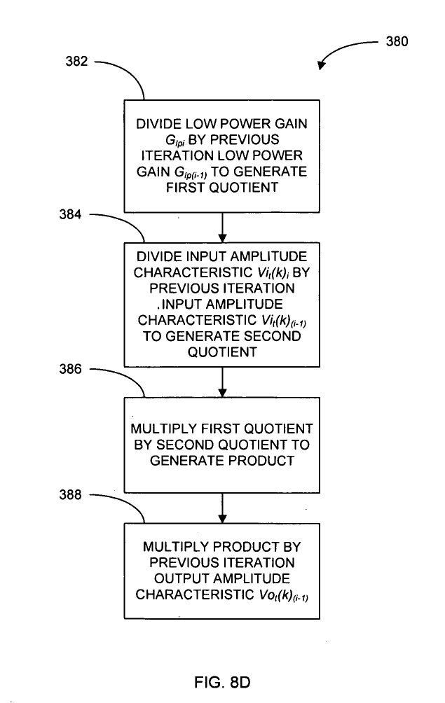

FIG. 10 illustrates a graph of exemplary saturation voltage response of a power amplifier pertaining to an exemplary baseline amplifier model, an exemplary adapted amplifier model where the saturation voltage has been adjusted higher, and an exemplary adapted amplifier model where the saturation voltage has been adjusted lower in accordance with another exemplary embodiment of the disclosure. As seen from the graph, the typical saturation voltage response of a power amplifier is characterized as generally linear for low input voltages, with the exception of a gain expansion region as previously discussed. At higher input voltages, the power amplifier operates in a nonlinear fashion typically causing the slope of the output voltage to decrease with respect to the input voltage.

If, for example, in the first adaptation cycle the measured peak voltage of the output RF signal of the power amplifier 206 is greater than the estimated peak voltage of the output RF signal, then according to Eq. 8, the saturated voltage of the adapted amplifier model is greater than the saturated voltage of the baseline amplifier model. According to Eqs. 9 and 10, the effects of a higher saturated voltage produces an increased power in the saturated region of the power amplifier model, as indicated by the graph. If, on the other hand, in the first adaptation cycle the measured peak voltage of the output RF signal is less than the estimated peak voltage of the output RF signal, then the saturated voltage of the new amplifier model is less than the saturated voltage of the baseline amplifier model. The effects of a lower saturated voltage produces a decreased power in the saturated region of the power amplifier model, as indicated by the graph.

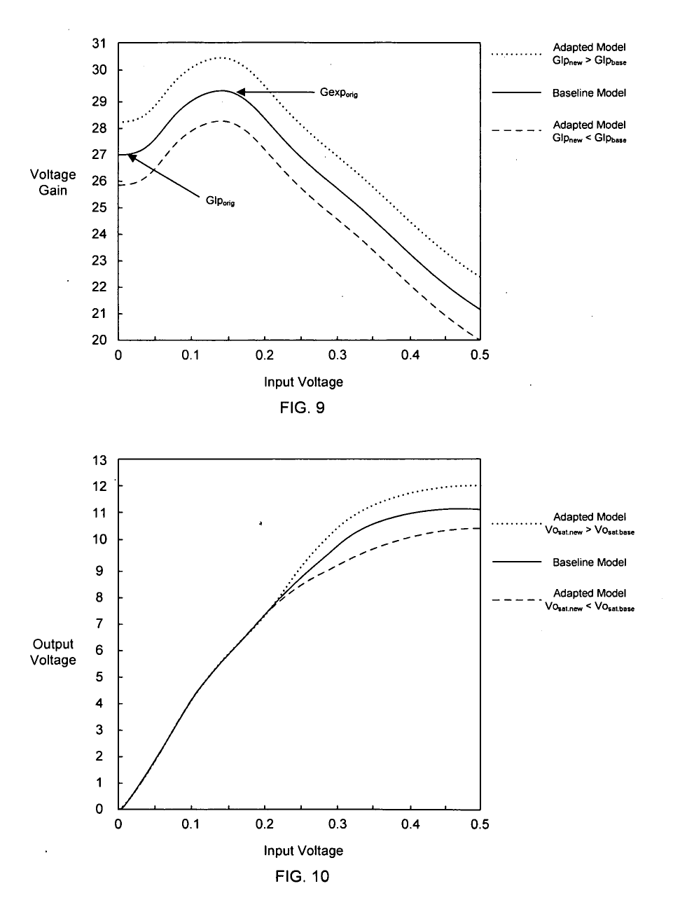

FIGS. 11A-C illustrate graphs of exemplary normalized output-input responses for the power amplifier, the predistortion device, and the transmitter system in accordance with another exemplary embodiment of the disclosure. The y-axis of the graphs indicates the normalized output voltage, where the value 1.0 indicates the target or specified maximum instantaneous output voltage of the power amplifier. The x-axis of the graphs indicates the normalized input voltage, where the value 1.0 indicates the input voltage that corresponds to the target or specified maximum instantaneous output voltage of the power amplifier. The upper graph (FIG. 11A) is an exemplary response where the average output power of the power amplifier 106 is set to a moderate level. The middle graph (FIG. 11B) is an exemplary response where the average output power is set to a relatively low level. The lower graph (FIG. 11C) is an exemplary response where the average output power is set to a relatively high level.

In these examples, the solid line on the graphs indicate the target or specified normalized output-input response for the transmitter system 200. As the graph illustrates, the target response may be primarily a linear response as indicated by the top and middle graphs. However, it shall be understood that the target response need not be substantially linear (FIG. 6C); e.g., clipping may occur. The dotted line of the graphs indicates the normalized input-output signal response for the power amplifier 206. The dashed line of the graphs indicates the normalized input-output signal response of the predistortion device 202. As these graphs illustrate, for a given normalized input level, the normalized input-output responses of the predistortion device 202 and the power amplifier 106 are situated on opposite sides of the target response. In this way, the input-output response of the predistortion device 202 combined with the input-output response of the power amplifier 206 should substantially produce the input-output target response for the transmitter system 200. As seen in FIG. 2, the predistortion device 202 receives an indication of the power level of the output RF signal via the RMS detector 212 for the purpose of indexing the adapted amplifier model and selecting the appropriate predistortion.

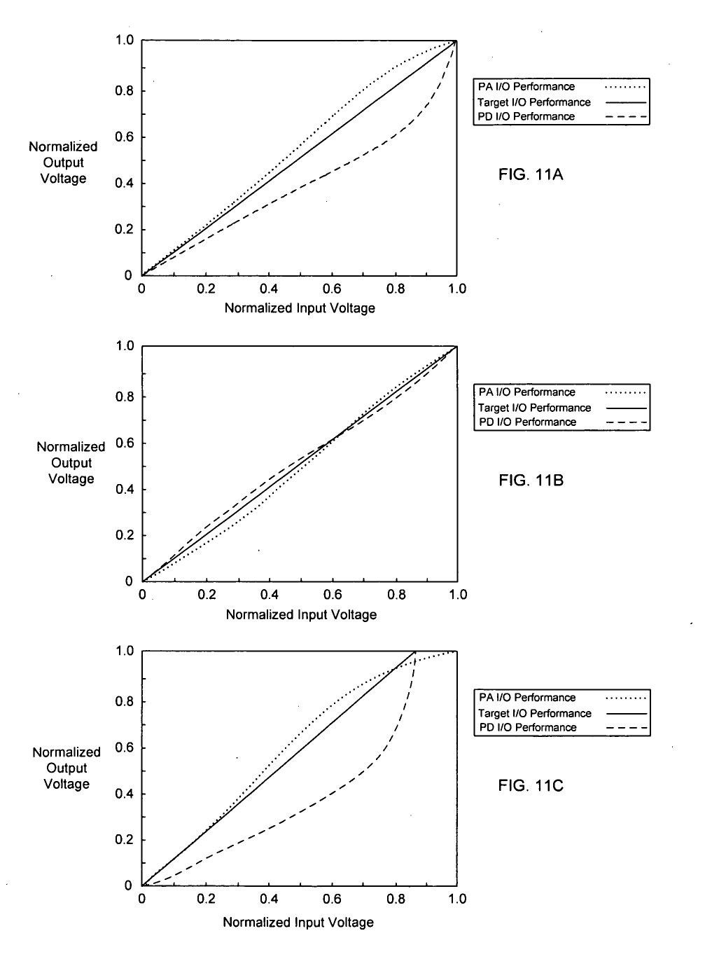

FIG. 12 illustrates a graph of an exemplary peak-to-average power ratio versus power for the input, output, and target output for the power amplifier 206 in accordance with another exemplary embodiment of the disclosure. The y-axis represents the peak-to-RMS ratio in dB for the corresponding signal, and the x-axis represents the average output power level in dBm for the corresponding signal. The dotted line represents the relationship between the peak-to-average power ratio to the average output power of the corrected output signal of the power amplifier 206. The dashed line represents the relationship between the peak-to-average power ratio to the average output power of the input signal of the power amplifier 206. And, the solid line represents the relationship between the peak-to-average power ratio to the power for the idealized or target output signal of the power amplifier 206.

As the graph illustrates, the peak-to-average power ratio value of the compensated output signal of the power amplifier 206 tracks the ideal values until the input signal hits the saturated power level, then decreases gradually above a power level of 17 dBm. This is due to the saturation properties of the power amplifier 206 that limit the maximum signal level. In order to compensate for the compression effects of the power amplifier 206, the predistortion device 202 performs signal crest enhancement by predistorting the input signal in order to increase the peak-to-average power ratio. This can be seen in the graph (from the dashed line) by the rise in the peak-to-RMS ratio of the input signal to the power amplifier 206. The overall effect of this compensation is to substantially maintain the peak-to-average ratio substantially constant over the operating range of the transmitter system 200, as illustrated by the substantially flat response of the power amplifier peak-to-average power ratio (dotted line), which is coincident with the target over the low and moderate power ranges.

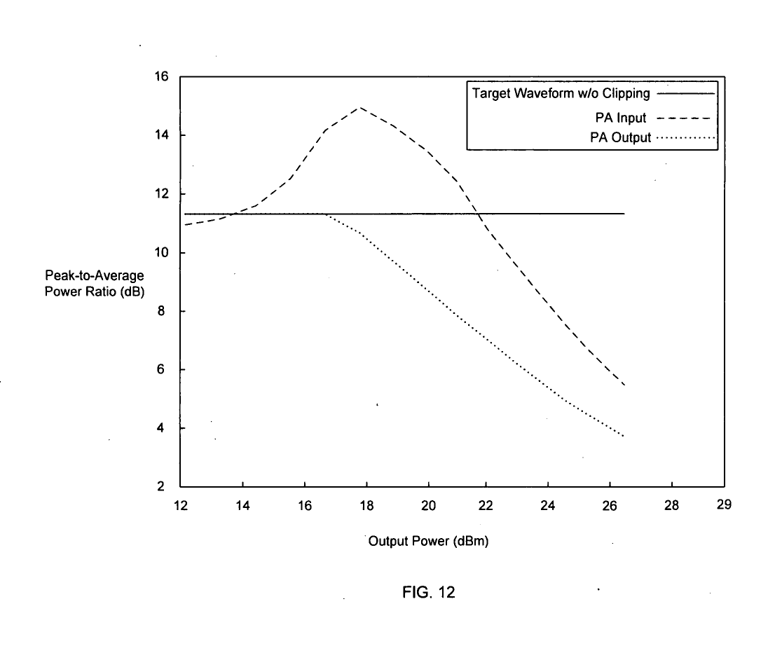

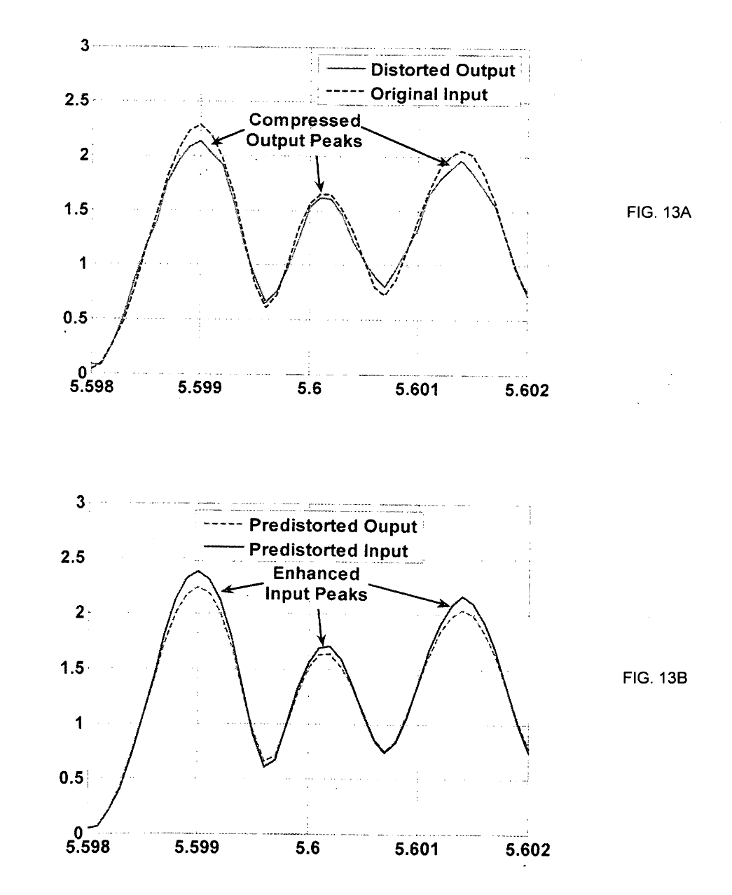

FIG. 13A illustrates a time-domain graph of exemplary undistorted or original input and corresponding distorted output signals in accordance with another exemplary embodiment of the invention. The y- or vertical axis represents amplitude of the signals, and the x- or horizontal axis represents time. As the graph illustrates, the original input signal shown as a dashed line may not have compressed peaks as shown. However, the output signal shown as a solid line may have compressed peaks due to the non-linear characteristic of the power amplifier when operated near its saturation region.

FIG. 13B illustrates a time-domain graph of exemplary predistorted input and output signals in accordance with another exemplary embodiment of the invention. Again, the y- or vertical axis represents amplitude of the signals, and the x- or horizontal axis represents time. As the graph illustrates, the input signal shown as a solid line has been predistorted by the predistortion device in order to enhanced its peaks as shown. The result is that the output signal shown as a dashed line no longer has compressed peaks. Thus, the amplifier modeling and predistortion techniques described herein may be used to achieve a target output signal, such as like the one shown in this graph.

With regard to generally the rate of providing information of the power amplifier output for the purpose of developing an amplifier model and predistorting an input signal based on the amplifier model, it can be done at any rate in accordance with the exemplary embodiments previously discussed. For instance, the rate may be at the modulation rate of the RF output signal, which could be as high as 200 GHz. Alternatively, the rate may be at the envelope rate (e.g., at the modulation bandwidth). Alternatively, the rate may be at the power control rate, which may depend on the modulation rate and a scheduler. Alternatively, the rate may be at the model evolution rate, which may be based on changes in the operation environment parameters, such as temperature, power supply voltage Vcc, and frequency of the signal. The model evolution rate may be updated as necessary, and could be as fast as or faster than the power control rate.

It shall be understood the elements of the transmitter system 200 discussed above may be implemented in the digital domain, analog domain, or a combination of the digital and analog domain. The system 200 may further use dedicated hardware, programmable hardware, processor operating under the control of one or more software modules, or any combination thereof, to perform its intended functions as discussed above.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A system, comprising:
an amplifier;
a device to measure a metric of the system during a sampling window exclusive of an absolute measured range of the metric;
a processor to generate a present model of an input-output signal characteristic of the amplifier based on the system metric; and
a predistortion device to predistort an input signal for the amplifier based on the present amplifier model.

2. The system of claim 1, wherein the metric measuring device comprises a detector for measuring a peak power or a peak voltage of an output signal of the amplifier.

3. The system of claim 1, wherein the processor generates the present model based on a baseline or predetermined model of the input-output signal characteristic of the amplifier.

4. The system of claim 1, wherein the processor generates the present model based on a previous model of the input-output signal characteristic of the amplifier.

5. The system of claim 1, wherein the predistortion device predistorts the input signal to achieve a target or specified output signal for the amplifier.

6. The system of claim 1, wherein the predistortion device predistorts the input signal to reduce distortion in an output signal of the amplifier.

7. The system of claim 1, wherein the processor generates the present model based on a measurement or estimate of an input voltage to the amplifier.

8. The system of claim 1, wherein the processor generates the present model by modifying a previous model of the input-output signal characteristic of the amplifier based on the system metric.

9. A method, comprising:
measuring a metric of a system including an amplifier during a sampling window exclusive of an absolute measured range of the metric;
generating a present amplifier model of an input-output signal characteristic of the amplifier based on the system metric; and
predistorting an input signal for the amplifier based on the present amplifier model.

10. The method of claim 9, wherein the system metric comprises a peak power or peak voltage of an output signal of the amplifier.

11. The method of claim 9, wherein the system metric comprises a plurality of samples of an output signal of the amplifier.

12. The method of claim 9, wherein the present amplifier model is based on a baseline or predetermined model of the input-output signal characteristic of the amplifier.

13. The method of claim 9, wherein the present amplifier model is based on a previous model of the input-output signal characteristic of the amplifier.

14. The method of claim 9, wherein predistorting the input signal comprises predistorting the input signal to achieve a target or specified output signal for the amplifier.

15. The method of claim 9, wherein predistorting the input signal comprises predistorting the input signal to reduce distortion in the output signal.

16. The method of claim 9, wherein generating the present model is further based on a measurement or estimate of an input voltage to the amplifier.

17. The method of claim 9, wherein generating the present model comprises modifying an input-output signal characteristic of a previous amplifier model based on the system metric.

18. An apparatus, comprising:
means for measuring a metric of a system including an amplifier during a sampling window exclusive of an absolute measured range of the metric;
means for generating a present amplifier model of an input-output signal characteristic of the amplifier based on the system metric; and
means for predistorting the input signal of the amplifier based on the present amplifier model.

19. The apparatus of claim 18, wherein the metric measuring means comprises a detector for measuring a peak power or a peak voltage of an output signal of the amplifier.

20. The apparatus of claim 18, wherein the present amplifier model is based on a baseline or predetermined model of the input-output signal characteristic of the amplifier.

21. The apparatus of claim 18, wherein the present amplifier model is based on a previous model of the input-output signal characteristic of the amplifier.

22. The apparatus of claim 18, wherein the predistorting means predistorts the input signal to achieve a target or specified output signal for the amplifier.

23. The apparatus of claim 18, wherein the predistorting means predistorts the input signal to reduce distortion in an output signal of the amplifier.

24. The apparatus of claim 18, wherein the present model generating means generates the present model of the input-output signal characteristic of the amplifier based on a measurement or estimate of an input voltage to the amplifier.

25. The apparatus of claim 18, wherein the present model generating means generates the present model by modifying an input-output signal characteristic of a previous model based on the system metric.

26. A computer program product, comprising:
computer-readable medium comprising:
code for causing a computer to measure a metric of a system including an amplifier during a sampling window exclusive of an absolute measured range of the metric;
code for causing a computer to generate a present model of an input-output signal characteristic of the amplifier based on the metric; and
code for causing a computer to predistort an input signal for the amplifier based on the present amplifier model.
